(19) United States
(12) Patent Application Publication
(10) Pub. No.: US 2017/0108656 A1
(43) Pub. Date: Apr. 20, 2017

(54) LIGHT-RECEIVING ELEMENT, OPTICAL MODULE, AND OPTICAL RECEIVER

(71) Applicant: NEC CORPORATION, Tokyo (JP)

(72) Inventor: Kazuhiro SHIBA, Tokyo (JP)

(73) Assignee: NEC CORPORATION, Tokyo (JP)

(21) Appl. No.: 15/128,690

(22) PCT Filed: Mar. 20, 2015
(86) PCT No.: PCT/JP2015/001581

§ 371 Date: Sep. 23, 2016

(30) Foreign Application Priority Data
Mar. 26, 2014 (JP) 2014-063740

(51) Int. Cl. G02B 6/42; H01L 31/0735; H01L 31/0745; H01L 31/0232; H01L 31/0216

(52) U.S. Cl. CPC G02B 6/4295; H01L 31/02327; H01L 31/02161; H01L 31/0745; H01L 31/0735; G02B 6/4215; G02B 6/4208

(57) ABSTRACT

Light-receiving elements and the like that can more simply absorb and transmit light are provided.

A Light-receiving element includes a lens unit condensing incident light to emit the light from an emission surface, an absorption layer arranged on the emission surface of the lens unit to absorb part of the condensed light and transmit the remaining condensed light, and a detection layer placed on the absorption layer to detect intensity of light emitted from the lens unit, on the basis of intensity of light absorbed by the absorption layer.

### TECHNICAL FIELD

The present invention relates to a light-receiving element and the like, and for example, to a light-receiving element and the like that include a lens and an absorption layer.

### BACKGROUND ART

It has been recently demanded to increase a capacity of a network. In order to cope with such an increase in the capacity of a network, digital coherent communication in which a signal is superposed on a light phase has been used widely from a metro system to a trunk line system.

An optical receiver 2000a used in such a technique has a configuration as illustrated in FIG. 6, for example. FIG. 6 is a block configuration diagram of a general optical receiver 2000a.

In the optical receiver 2000a, a signal light incident port 200 emits incident signal light to the side of an optical function circuit 500. A local oscillation light incident port 300 emits, to the side of the optical function circuit 500, local oscillation light incident from a local oscillation light source 900.

Lenses 410 to 430 refract signal light or local oscillation light emitted from the signal light incident port 200 or the local oscillation light incident port 300, into collimated light, and then condense the light to optical function circuit incident ports 510 and 520 on the side of the optical function circuit 500.

The optical function circuit 500 divides signal light that enters from the signal light incident port 200 via the lenses 410 and 420, into X polarized signal light and Y polarized signal light. The optical function circuit 500 multiplexes each of the divided X polarized signal light and Y polarized signal light with the local oscillation light that enters from the local oscillation light incident port 300 via the lens 430, and emits the multiplexed light signals (referred to as interference signals in the section of Background Art) to detection light-receiving elements 610 and 620 constituted by four channels.

The detection light-receiving elements 610 and 620 convert the interference signals incident from the optical function circuit 500, into electric signals to output the electric signals.

An optical branch device 440 is arranged between the lens 410 and the lens 420, emits, to the side of the lens 420, the signal light that is converted into collimated light in the lens 410, and emits, to the side of a monitoring light-receiving element 700, part of the signal light (referred to as measurement signal light in the section of Background Art). The monitoring light-receiving element 700 detects intensity of the measurement signal light incident from the optical branch device 440. The local oscillation light source 900 generates local oscillation light in accordance with intensity of the measurement signal light detected by the monitoring light-receiving element 700.

Thus, in the optical receiver 2000a, the local oscillation light source 900 generates local oscillation light in accordance with intensity of the measurement signal light detected by the monitoring light-receiving element 700.

For example, the PTL 1 describes, as a technique related to the above, a technique of a light transmission and reception module including a light-receiving element that absorbs part of light, and transmits the remaining light.

### CITATION LIST

### Patent Literature

[PTL 1] Japanese Patent Application Laid-open Publication No. H11-52199

### SUMMARY OF INVENTION

### Technical Problem

In the optical receiver 2000a exemplified in FIG. 6, it is however necessary that the optical branch device 440 for emitting measurement signal light to the side of the monitoring light-receiving element 700, and the monitoring light-receiving element 700 for detecting intensity of measurement signal light be arranged in the vicinity of the lenses 410 and 420. Further, in order to generate collimated light, the two lenses 410 and 420 are needed. For these reasons, the number of components in the vicinity of the lenses 410 and 420 is increased, and assembling man-hours are increased.

In view of such a circumstance, the present invention has been made, and an object thereof is to provide a light-receiving element and the like that can more simply absorb and transmit light.

### Solution to Problem

A light-receiving element according to the present invention includes a lens unit that condenses incident light to emit the light from an emission surface, an absorption layer that is arranged on the emission surface of the lens unit to absorb part of the condensed light and transmit the remaining condensed light, and a detection layer that is placed on the absorption layer to detect intensity of light emitted from the lens unit, on the basis of intensity of light absorbed by the absorption layer.

An optical receiver according to the present invention includes the above-described light-receiving element that condenses and transmits incident signal light, and a control unit that performs predetermined control on the basis of intensity of light detected by the light-receiving element.

An optical module according to the present invention includes a signal light emission unit that emits signal light, the above-described light-receiving element that condenses and transmits the emitted signal light, a local oscillation light emission unit that emits local oscillation light, a lens unit that condenses the emitted local oscillation light, a multiplexing unit that multiplexes signal light that passes through the light-receiving element and the condensed local oscillation light to emit a multiplexed light signal, and a conversion unit that converts a multiplexed light signal emitted from the multiplexing unit, into an electric signal, wherein the local oscillation light emission unit adjusts intensity of local oscillation light to be emitted, on the basis of intensity of light detected by the light-receiving element.

### Advantageous Effects of Invention

According to a light-receiving element and the like of the present invention, it is possible to more simply absorb and transmit light.

### BRIEF DESCRIPTION OF DRAWINGS

FIG. 1 is a side view of an optical monitoring function integrated lens 100 according to a first exemplary embodiment.

FIG. 2 is a rear view of the optical monitoring function integrated lens 100 according to the first exemplary embodiment.

FIG. 3 is a diagram illustrating an example of relation between a thickness and an absorption ratio of an absorption layer 130 according to the first exemplary embodiment.

FIG. 4 is a diagram illustrating a configuration of an optical receiver 2000 according to a second exemplary embodiment.

FIG. 5 is an enlarged view of the vicinity of an optical monitoring function integrated lens 100 according to the second exemplary embodiment.

FIG. 6 is a configuration diagram of an optical receiver of the related art.

### DESCRIPTION OF EMBODIMENTS

### First Exemplary Embodiment

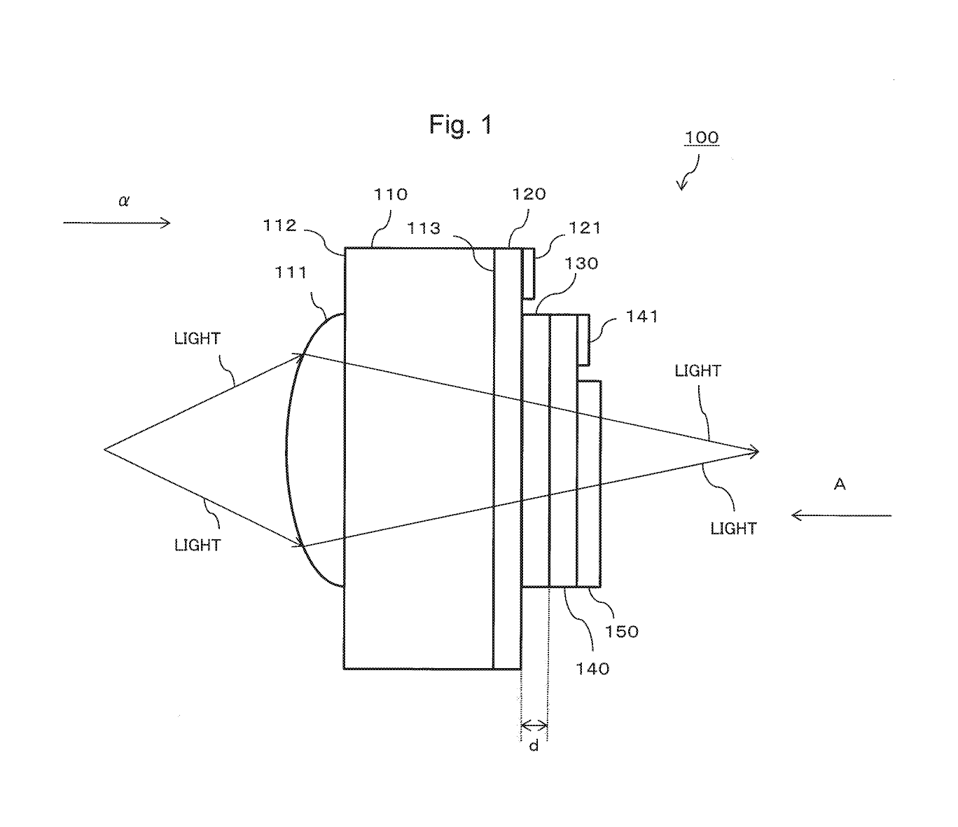

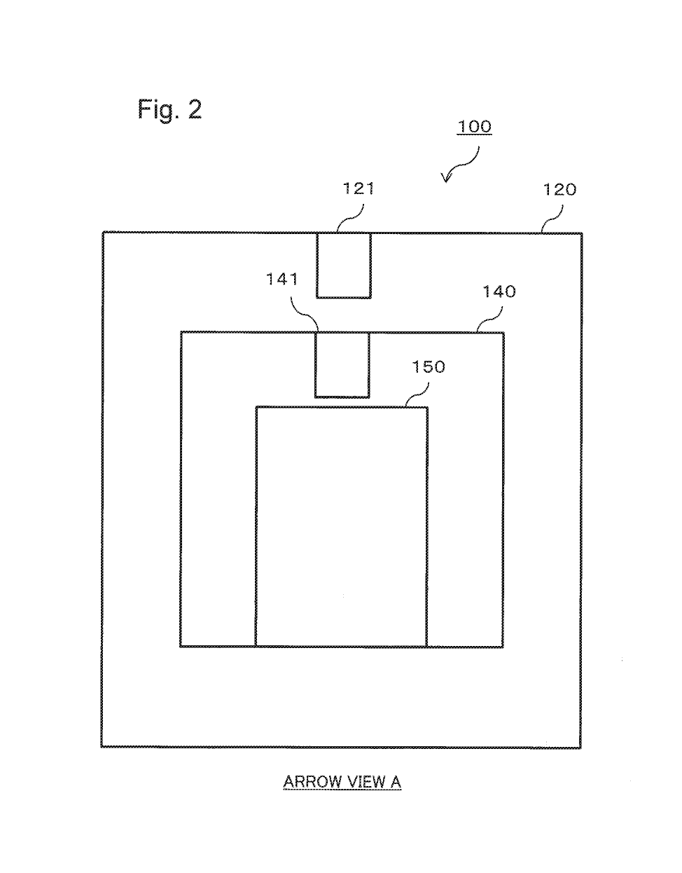

An optical monitoring function integrated lens according to a first exemplary embodiment is described using FIG. 1 and FIG. 2. FIG. 1 is a side view of the optical monitoring function integrated lens 100. FIG. 2 is a rear view of the optical monitoring function integrated lens 100, taken from the arrow view A in FIG. 1. In FIG. 1, light advances from the left side to the right side. In other words, the α direction indicated in FIG. 1 corresponds to the advancing direction of light. In the present exemplary embodiment, light having a wavelength from 1.31 to 1.61 μm is used.

In FIG. 1, the optical monitoring function integrated lens 100 includes a lens 110, an n-type semiconductor 120, an absorption layer 130, a p-type semiconductor 140, and a non-refection film 150. The n-type semiconductor 120, the absorption layer 130, and the p-type semiconductor 140 constitute a light-receiving element.

The lens 110 transmits incident light to the side of the n-type semiconductor 120 while condensing the incident light. When light having a wavelength of 1.31 to 1.61 μm enters the optical monitoring function integrated lens 100, the lens 110 is formed of, e.g., Si that is a material having transparency to a wavelength of 1.31 to 1.61 μm.

As illustrated in FIG. 1, the lens 110 includes a convex portion 111, a first main surface 112, and a second main surface 113. The convex portion 111 is formed into a convex shape, a spherical surface, or an approximately spherical surface shape like a general glass lens. The convex portion 111 refracts and condenses incident light. The light that has entered from the convex portion 111 to the first main surface 112 passes through the lens 110 to be thereby condensed and emitted from the second main surface 113.

The n-type semiconductor 120 is provided on an emission surface (second main surface 113) of the lens 110, and transmits the light incident from the second main surface 113 as it is, to emit this light to the absorption layer 130. When the lens 110 is formed of Si, the n-type semiconductor 120 is formed of Si as well. In the present exemplary embodiment, the n-type semiconductor 120 is formed into a thin film of which main ingredient is Si, of which impurity concentration is 5×10¹⁸ [cm⁻³], and of which thickness in the α direction is 0.5 [μm]. The n-type semiconductor 120 functions as a conductive layer extracting an electric current depending on intensity of light absorbed by the absorption layer 130. The n-type semiconductor 120 includes an n-type-semiconductor-side electrode 121. The n-type-semiconductor-side electrode 121 is provided, on the n-type semiconductor 120, at a position where the light does not enter. The n-type-semiconductor-side electrode 121 outputs, as an electric current I [A], intensity (absorbed light intensity) P1 [W] of the light absorbed by the absorption layer 130.

The absorption layer 130 is provided between the n-type semiconductor 120 and the p-type semiconductor 140 so as to face the second main surface 113 of the lens 110. The absorption layer 130 absorbs a part of the light incident from the n-type semiconductor 120, and transmits the remaining light to the p-type semiconductor 140. When the lens 110, the n-type semiconductor 120, and the p-type semiconductor 140 are formed of Si, the absorption layer 130 is formed of Ge or SiGe, for example.

An area of the absorption layer 130 is set larger than a transmission region of the light. A thickness d of the absorption layer 130 is set in accordance with an absorption rate of the absorption layer 130. While a too small absorption quantity of the light in the absorption layer 130 causes decline in detection accuracy of intensity of the light, a too large absorption quantity of it causes decline in main signal power, resulting in decline in reception sensitivity. Since an absorption quantity is desirably the minimum intensity necessary for the system, a thickness d of the absorption layer 130 is desirably set such that an absorption quantity is at least 5% of all the incident light quantity and at most 20% of all the incident light quantity. In the present exemplary embodiment, a thickness d of the absorption layer 130 is set such that an absorption rate is from 5% to 10%. An absorption rate is defined as a rate of an absorbed light intensity P1 [W] to intensity P2 [W] of the incident light.

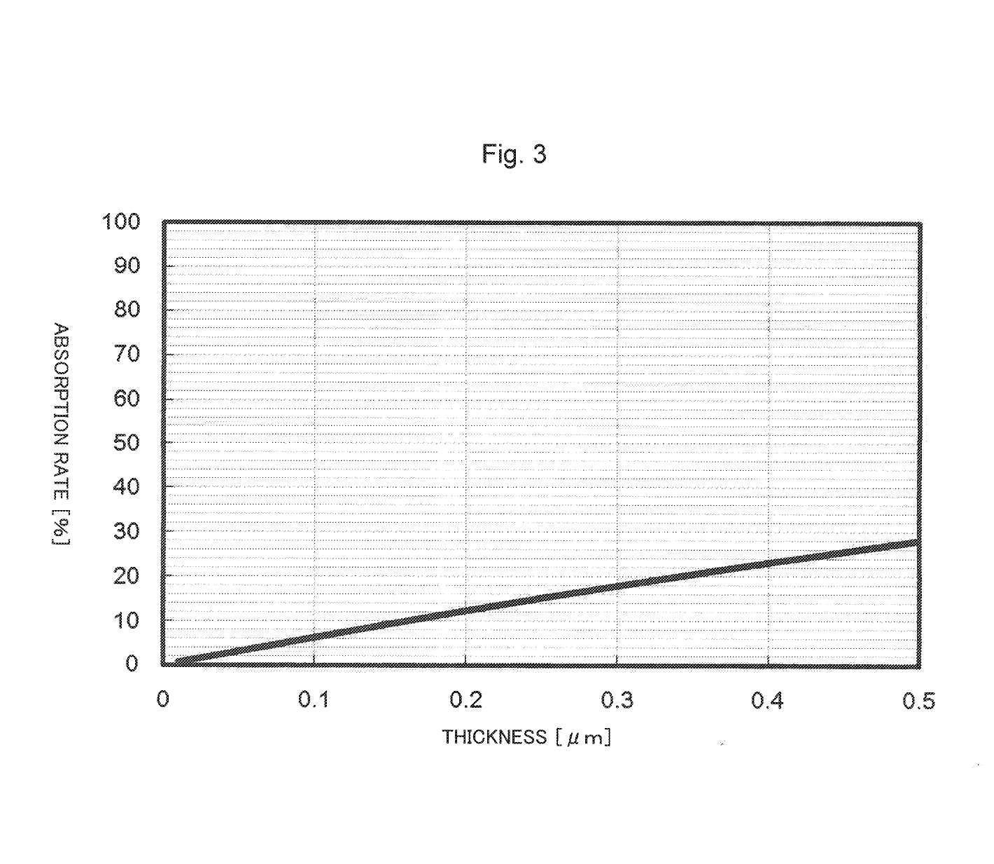

Relation between a thickness d and an absorption rate of the absorption layer 130 is illustrated in FIG. 3. Regarding FIG. 3, a wavelength of light incident on the absorption layer 130 is 1.55 [μm]. In FIG. 3, when an absorption rate of the absorption layer 130 is at least 5 [%] and at most 10 [%] for example, a thickness d of the absorption layer 130 is set between 0.1 [μm] and 0.15 [μm]

The p-type semiconductor 140 is provided on the absorption layer 130 to transmit the light incident from the absorption layer 130 as it is, and emit this light to the non-reflection film 150. When the n-type semiconductor 120 is formed of Si, the p-type semiconductor 140 is formed of Si as well. In the present exemplary embodiment, the p-type semiconductor 140 is formed into a thin film of which main ingredient is Si, of which impurity concentration is 5×10¹⁸ [cm⁻³], and of which thickness in the α direction is 0.5 [μm]. The p-type semiconductor 140 functions as a conductive layer extracting an electric current depending on intensity of light absorbed by the absorption layer 130. The p-type semiconductor 140 includes a p-type-semiconductor-side electrode 141. The p-type-semiconductor-side electrode 141 is provided, on the p-type semiconductor 140, at a position where the light does not enter. The p-type-semiconductor-side electrode 141 functions in the same manner as the n-type-semiconductor-side electrode 121, and outputs, as an electric current I [A], intensity (absorbed light intensity) P1 [W] of the light absorbed by the absorption layer 130.

An absorption quantity of the light in the absorption layer 130 is proportional to intensity of the light passing through the absorption layer 130. Since a light absorption quantity (absorbed light intensity) P1 is proportional to an electric current I extracted from the n-type-semiconductor-side electrode 121 and the p-type-semiconductor-side electrode 141, monitoring an electric current I extracted from the n-type-semiconductor-side electrode 121 and the p-type-semiconductor-side electrode 141 makes it possible to monitor intensity of the light passing through the absorption layer 130.

When the n-type semiconductor 120 and the p-type semiconductor 140 are formed of Si, and the absorption layer 130 is formed of Ge, it is difficult to perform epitaxial growth because of difference in a lattice spacing between Si and Ge. However, since as described above, it is sufficient that the absorption layer 130 can secure a necessary minimum absorption quantity, a thickness d of the absorption layer 130 may be approximately 0.1 to 0.15 [μm]. For this reason, the absorption layer 130 formed of Ge can be formed between the n-type semiconductor 120 and the p-type semiconductor 140 that are formed of Si.

The non-reflection film 150 is formed on an emission surface of the p-type semiconductor 140 to suppress reflection of the incident light. The non-reflection film 150 transmits the light incident from the p-type semiconductor 140 as it is, to emit the light to the outside. When the p-type semiconductor 140 is formed of Si, the non-reflection film 150 is formed of an SiN-based material or an SiON-based material, for example. The non-reflection film 150 does not necessarily need to be arranged.

As described above, in the optical monitoring function integrated lens 100 according to the present exemplary embodiment, the light-receiving element including the n-type semiconductor 120, the absorption layer 130, and the p-type semiconductor 140 is arranged on the emission surface (second main surface 113) of the lens 110. The absorption layer 130 absorbs a part of the light emitted from the lens 110, and intensity of the absorbed light is extracted as an electric current I in the n-type semiconductor 120 and the p-type semiconductor 140 so that intensity of the light passing through the absorption layer 130 is detected.

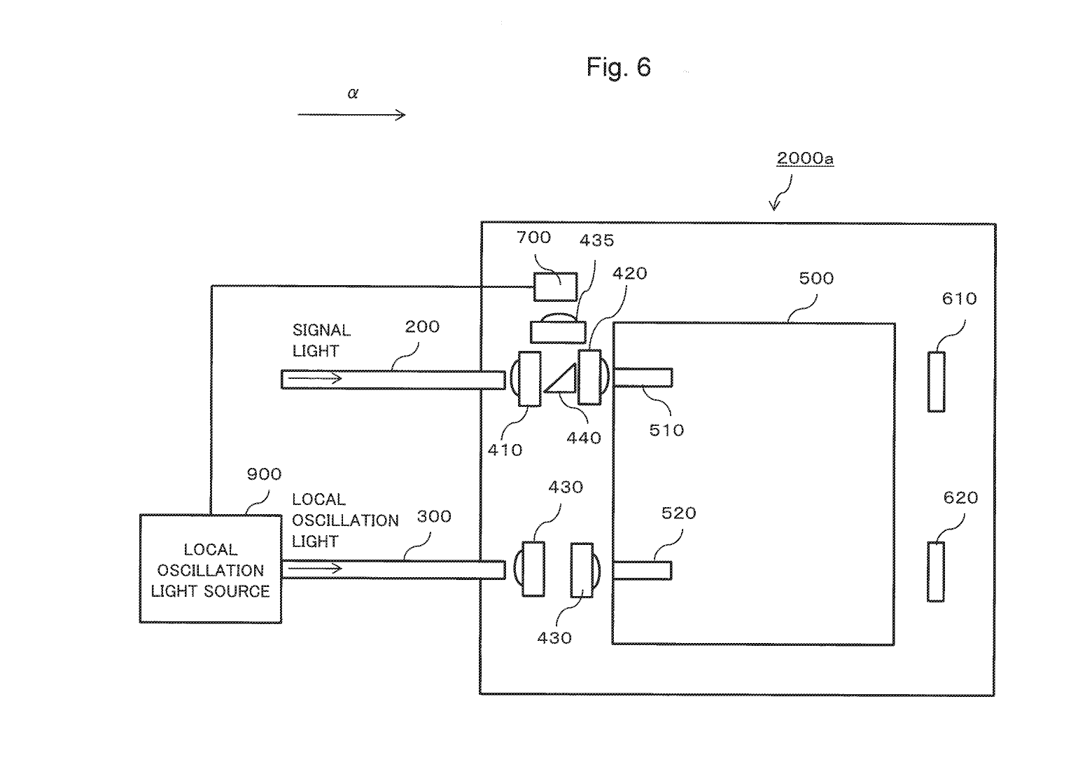

Setting a thickness d of the absorption layer 130 such that an absorption rate becomes at least 5% enables the local oscillation light source 900 to be controlled on the basis of an electric current I detected at the n-type-semiconductor-side electrode 121 and the p-type-semiconductor-side electrode 141 in the case of application to the optical receiver 2000a in FIG. 6 described in the Background Art, for example.

Meanwhile, setting a thickness d of the absorption layer 130 such that an absorption rate becomes at most 20% suppresses an absorbed quantity in the absorption layer 130 to the minimum quantity necessary for detection of intensity of the light so that influence on a main signal can be minimized. In this case, the light-receiving element including the n-type semiconductor 120, the absorption layer 130, and the p-type semiconductor 140 can be formed into a film thinner than a general light-receiving element.

When the n-type semiconductor 120 and the p-type semiconductor 140 are formed of Si, and the absorption layer 130 is formed of Ge, the absorption layer 130 grows at most to a thickness by which crystallinity can be kept, because of lattices of Si and Ge that do not match each other. Thereby, the light-receiving element including the n-type semiconductor 120, the absorption layer 130, and the p-type semiconductor 140 can be formed into a film thinner than the light-receiving element of the PTL 1 described in the Background Art.

Further, in the optical monitoring function integrated lens 100 according to the present exemplary embodiment, when the light-receiving element including the n-type semiconductor 120, the absorption layer 130, and the p-type semiconductor 140 is arranged on the emission surface of the lens 110, the optical branch device 440 and the monitoring light-receiving element 700 described in the Background Art do not need to be arranged. Since this configuration does not need a prism that branches light, a collimation region for arranging the prism is unnecessary, enabling an incident main signal to be directly condensed by one lens. Accordingly, the optical monitoring function integrated lens 100 according to the present exemplary embodiment can decrease the number of components, and have a smaller size. Additionally, since the optical branch device 440 and the monitoring light-receiving element 700 for which strict mounting precision is necessary do not need to be arranged, drastic reduction in assembling man-hours can be accomplished.

In the present exemplary embodiment, the lens 110, the n-type semiconductor 120, and the p-type semiconductor 140 are formed of Si, and the absorption layer 130 is formed of Ge or SiGe, without being limited to this. It is sufficient that the lens 110, the n-type semiconductor 120, and the p-type semiconductor 140 are transparent to a used wavelength. In the case of application to a wavelength (1.31 μm to 1.61 μm) of light used in digital coherent communication, InP for example can be used as a material. In this case, InGaAs, InGaAsP, or the like can be used as a material of the absorption layer 130. When InGaAsP is used as a material of the absorption layer 130, a thickness d can be designed to be large in obtaining a predetermined absorption rate because light absorption efficiency of InGaAsP is smaller than absorption efficiency of Ge, SiGe, InGaAs, or the like. In this case, manufacturing tolerance of the absorption layer 130 is improved.

Using the optical monitoring function integrated lens 100 according to the present exemplary embodiment for a digital coherent module can simultaneously implement a light condensing function of condensing a signal emitted from an incident port to be optically coupled to a port of an optical function circuit, and a function of detecting signal light intensity.

### Second Exemplary Embodiment

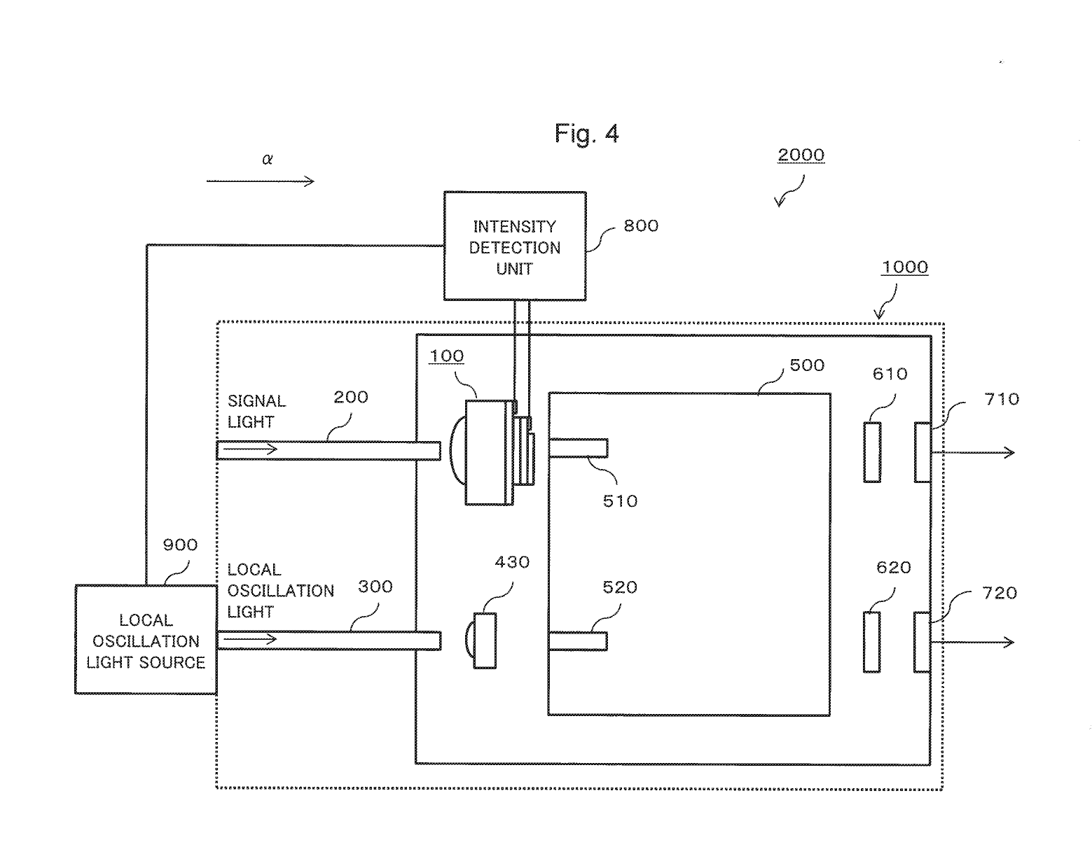

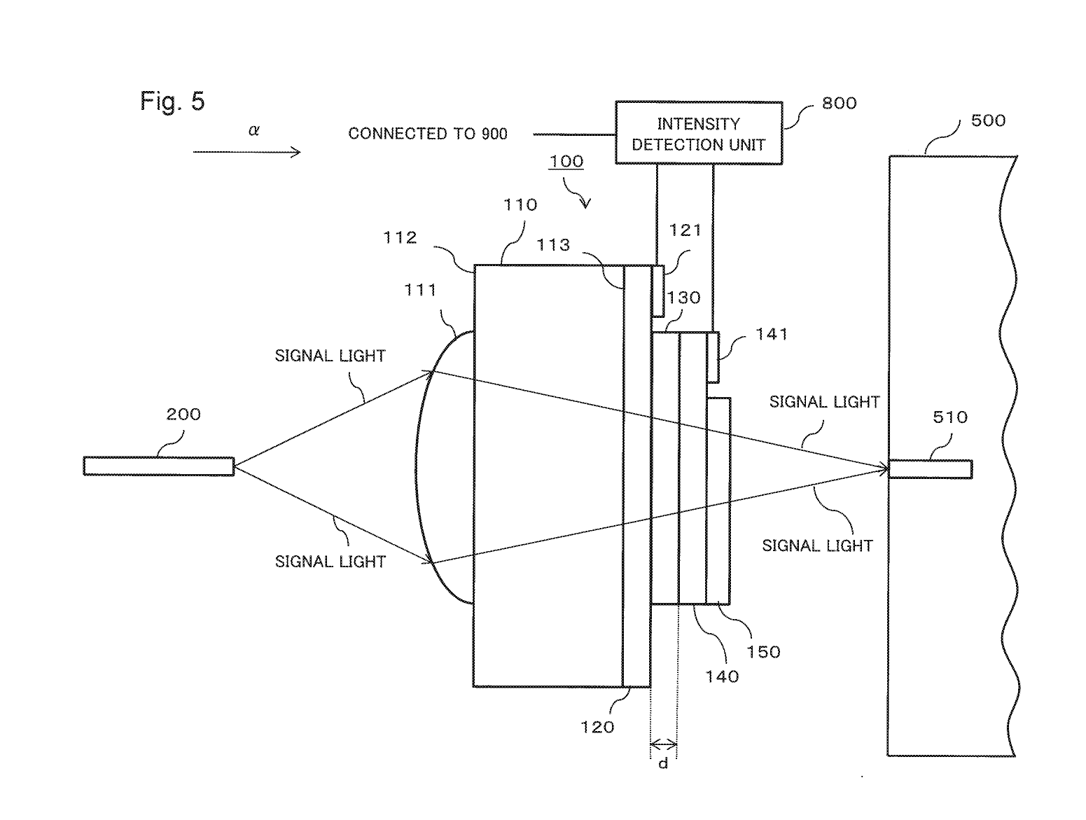

An optical receiver 2000 according to the second exemplary embodiment is described. FIG. 4 is a configuration diagram of the optical receiver 2000 including an optical module 1000. FIG. 5 is an enlarged view of the vicinity of the optical monitoring function integrated lens 100 in the optical receiver 2000 in FIG. 4. In FIG. 4 and FIG. 5, illustrations of the optical monitoring function integrated lens 100 are enlarged for convenience of description. The α direction in FIG. 4 and FIG. 5 corresponds to the advancing direction of signal light and local oscillation light. For example, the signal light is supposed to be light of a wavelength from 1.31 [μm] to 1.61 [μm] frequently used in digital coherent communication. In FIG. 4 and FIG. 5, the same reference symbols as those expressed in FIG. 1 and FIG. 2 are attached to the constituent elements equivalent to the constituent elements illustrated in FIG. 1 and FIG. 2. In the following, description is omitted for the configuration equivalent to the configuration described in the first exemplary embodiment.

The optical receiver 2000 includes an intensity detection unit 800, a local oscillation light source 900, and the optical module 1000. The optical receiver 2000 is referred to as a digital coherent optical receiver as well.

The intensity detection unit 800 is connected to the n-type-semiconductor-side electrode 121 and the p-type-semiconductor-side electrode 141 of the optical monitoring function integrated lens 100. The intensity detection unit 800 detects an electric current I [A] output from the n-type-semiconductor-side electrode 121 and the p-type-semiconductor-side electrode 141 to thereby acquire intensity (absorbed light intensity P1 [W]) of signal light absorbed by the absorption layer 130.

An absorbed light intensity P1 [W] in the absorption layer 130 is proportional to intensity of signal light passing through the absorption layer 130. Since an absorbed light intensity P1 [W] in the absorption layer 130 is proportional to an electric current I extracted from the n-type-semiconductor-side electrode 121 and the p-type-semiconductor-side electrode 141, monitoring an electric current I extracted from the n-type-semiconductor-side electrode 121 and the p-type-semiconductor-side electrode 141 enables intensity of the signal light to be monitored. In this regard, the optical monitoring function integrated lens 100 and the intensity detection unit 800 can constitute an optical receiver. In this case, the intensity detection unit 800 detects an electric current I [A] output from the n-type-semiconductor-side electrode 121 and the p-type-semiconductor-side electrode 141 of the optical monitoring function integrated lens 100 to thereby perform, on various circuits, control depending on intensity of the incident signal light. The intensity detection unit 800 in this case functions as a control unit in claims.

Description returns to that for the optical receiver 2000 in FIG. 4. The local oscillation light source 900 is connected to the intensity detection unit 800 and the local oscillation light incident port 300. The local oscillation light source 900 adjusts intensity P3 [W] of local oscillation light in accordance with absorbed light intensity P1 [W] acquired by the intensity detection unit 800, to generate local oscillation light.

The optical module 1000 includes the optical monitoring function integrated lens 100, the signal light incident port 200, the local oscillation light incident port 300, the lens 430, the optical function circuit 500, the detection light-receiving elements 610 and 620, and output terminals 710 and 720.

The signal light incident port 200 emits, to the side of the optical monitoring function integrated lens 100, signal light in which a signal is superposed on a light phase emitted from the outside (e.g., a digital coherent optical transmitter). For the signal light incident port 200, an optical fiber can be used, for example. Intensity of the signal light emitted from the signal light incident port 200 is from 0.01 to 10 [mW], for example. The signal light incident port 200 corresponds to a signal light emission unit in the claims.

The optical monitoring function integrated lens 100 condenses signal light incident from the signal light incident port 200 to emit this light to the optical function circuit incident port 510. Since the optical monitoring function integrated lens 100 is the same as the optical monitoring function integrated lens 100 in FIG. 1 and FIG. 2 described in the first exemplary embodiment, its description is omitted.

In other words, the optical monitoring function integrated lens 100 is constituted by the lens 110 and the light-receiving element. The lens 110 condenses incident signal light at the convex portion 111 arranged on the first main surface 112 that is an incident surface, and emits the condensed signal light to the light-receiving element arranged on the second main surface 113 that is an emission surface. The light-receiving element is constituted by the n-type semiconductor 120, the absorption layer 130, and the p-type semiconductor 140. The light-receiving element absorbs a part of the incident signal light in the absorption layer 130 to detect intensity of the absorbed signal light at the n-type semiconductor 120 and the p-type semiconductor 140, and emits the remaining signal light to the optical function circuit incident port 510 of the optical function circuit 500.

The local oscillation light incident port 300 emits, to the side of the lens 430, the local oscillation light emitted from the local oscillation light source 900. For the local oscillation light incident port 300, an optical fiber can be used, for example. The local oscillation light incident port 300 corresponds to a local oscillation light emission unit in the claims.

The lens 430 condenses the local oscillation light emitted from the local oscillation light incident port 300, to emit this light to the optical function circuit incident port 520 of the optical function circuit 500.

The optical function circuit 500 includes an optical 90 degree hybrid (not illustrated) for example, and divides the signal light incident from the optical monitoring function integrated lens 100 into X polarized signal light and Y polarized signal light. Further, the optical function circuit 500 multiplexes, with each of the divided X polarized signal light and Y polarized signal light, the local oscillation light that has entered via the lens 430 from the local oscillation light source 900. Then, the optical function circuit 500 emits the multiplexed signals (hereinafter, referred to as interference signals) to the detection light-receiving elements 610 and 620. The optical function circuit 500 corresponds to a multiplexing unit in the claims.

As illustrated in FIG. 4, the optical function circuit 500 includes the optical function circuit incident ports 510 and 520. The optical function circuit incident port 510 emits the signal light incident from the optical monitoring function integrated lens 100, into the optical function circuit 500. The optical function circuit incident port 520 emits the local oscillation light incident from the lens 430, into the optical function circuit 500.

The detection light-receiving elements 610 and 620 receive the interference signals emitted from the optical function circuit 500, and convert these signals into analog electric signals to output the converted signals to the output terminals 710 and 720. For the detection light-receiving elements 610 and 620, photodiodes (PD) can be used, for example. When the optical receiver 2000 is a digital coherent optical receiver, the detection light-receiving elements 610 and 620 are constituted by four channels. Note that the detection light-receiving elements 610 and 620 correspond to a conversion unit in the claims.

The output terminals 710 and 720 are output terminals connected to an external device. Examples of the external device include a transimpedance amplifier (TIA) and the like. When the TIA is connected to the output terminals 710 and 720, the electric signals output from the detection light-receiving elements 610 and 620 are input to the TIA via the output terminals 710 and 720. The electric signals input to the TIA are converted into voltage signals by the TIA. The voltage signals into which conversion has been made by the TIA are then subjected to demodulation and a predetermined signal process at analog digital converter (ADC) circuit, a digital signal processor (DSP) circuit, or the like, for example.

In the optical receiver 2000 configured as described above, the intensity detection unit 800 detects intensity (absorbed light intensity) of signal light absorbed by the absorption layer 130 of the optical monitoring function integrated lens 100. Then, in accordance with the absorbed light intensity detected by the intensity detection unit 800, the local oscillation light source 900 generates local oscillation light.

In this case, it becomes unnecessary to arrange, in the optical module 1000, the optical branch device 440 and the monitoring light-receiving element 700 described in the Background Art, it becomes unnecessary to provide a collimation region for arranging a prism, and it is possible to directly condense the incident signal light by the one lens. Accordingly, the optical receiver 2000 according to the exemplary embodiment can decrease the number of components, and can have a smaller size. Further, since the optical branch device 440 and the monitoring light-receiving element 700 for which strict mounting precision is necessary do not need to be arranged, it is possible to accomplish drastic reduction in assembling man-hours.

The invention of the present application is not limited to the above-described exemplary embodiment, and this invention encompasses even design change or the like within a scope that does not depart from the essence of this invention. A part or all of the above-described exemplary embodiments can be written as the following supplementary notes, without being limited to the following.

### [Supplementary Note 1]

A light-receiving element including: a lens including an incident surface that light enters, and an emission surface that emits the light incident from the incident surface; and an absorption layer provided so as to face the incident surface or the emission surface, and absorbing and transmitting incident light, wherein lattices of the absorption layer and the lens do not match each other.

### [Supplementary Note 2]

The light-receiving element according to the supplementary note 1, wherein a main ingredient of the lens is Si.

### [Supplementary Note 3]

The light-receiving element according to the supplementary note 1 or 2, wherein a main ingredient of the absorption layer is Ge or SiGe.

### [Supplementary Note 4]

The light-receiving element according to any one of the supplementary notes 1 to 3, wherein the absorption layer is formed such that an absorption rate thereof at which the incident light is absorbed becomes at least 5% and at most 20%.

### [Supplementary Note 5]

The light-receiving element according to any one of the supplementary notes 1 to 4, wherein the absorption layer is formed such that a thickness of the absorption layer is at least 0.1 μm and at most 0.5 μm.

### [Supplementary Note 6]

An optical receiver including:

a light-receiving element that includes a lens including an incident surface that light enters and an emission surface that emits the light incident from the incident surface, and an absorption layer provided so as to face the incident surface or the emission surface and absorbing and transmitting incident light;

an intensity detection unit that detects absorbed light intensity that is intensity of light absorbed by the absorption layer; and

a local oscillation light source that generates local oscillation light, wherein

in accordance with the absorbed light intensity detected by the intensity detection unit, the local oscillation light source generates the local oscillation light.

### [Supplementary Note 7]

An optical module including:

a signal light emission unit that emits signal light;

a local oscillation light emission unit that emits local oscillation light;

a light-receiving element that includes a lens including an incident surface that signal light emitted from the signal light emission unit enters and an emission surface that emits the signal light incident from the incident surface, and an absorption layer provided so as to face the incident surface or the emission surface and absorbing and transmitting incident signal light;

a multiplexing unit that multiplexes, with each other, signal light emitted from the lens and local oscillation light emitted from the local oscillation light emission unit, and emits a multiplexed light signal; and a conversion unit that converts a multiplexed light signal emitted from the multiplexing unit, into an electric signal.

### INDUSTRIAL APPLICABILITY

The invention of the present application can be widely applied to optical communication devices performing various kinds of control on the basis of intensity of incident signal light.

This application claims priority based on Japanese application Japanese Patent Application No. 2014-063740, filed on Mar. 26, 2014, the disclosure of which is incorporated herein in its entirety.

### REFERENCE SIGNS LIST

100 Optical monitoring function integrated lens
110 Lens
111 Convex portion
112 First main surface
113 Second main surface
120 N-type semiconductor
121 N-type-semiconductor-side electrode
130 Absorption layer
140 P-type semiconductor
141 P-type-semiconductor-side electrode
150 Non-reflection film
200 Signal light incident port
300 Local oscillation light incident port
410, 420, 430 Lens
440 Optical branch device
500 Optical function circuit
510, 520 Optical function circuit incident port
610, 620 Detection light-receiving element
700 Monitoring light-receiving element
800 Intensity detection unit
900 Local oscillation light source
1000 Optical module
2000, 2000a Optical receiver

1. A light-receiving element comprising:
a lens unit that condenses incident light to emit the light from an emission surface;
an absorption layer that is arranged on the emission surface of the lens unit to absorb part of the condensed light and transmit the remaining condensed light; and
a detection layer that is placed on the absorption layer to detect intensity of light emitted from the lens unit, based on intensity of light absorbed by the absorption layer.

2. The light-receiving element according to claim 1, wherein the absorption layer is formed to have a thickness that absorbs at least 5% and at most 20% of condensed light.

3. The light-receiving element according to claim 1, wherein the detection layer transmits incident light, and an electrode that outputs, as an electric current, intensity of the absorbed light is arranged at a region that light does not enter.

4. The light-receiving element according to claim 1, wherein the detection layer is constituted by a first detection layer arranged on a side of an incident surface of the absorption layer, and a second detection layer arranged on a side of an emission surface of the absorption layer.

5. The light-receiving element according to claim 1, wherein a non-reflection film is arranged on a surface of the second detection layer on a side opposite to a side on which the absorption layer is arranged.

6. The light-receiving element according to claim 1, wherein the lens unit and the detection layer are formed each using Si as a main ingredient, and
the absorption layer is formed using Ge or SiGe as a main ingredient.

7. The light-receiving element according to claim 1, wherein the lens unit and the detection layer are formed each using InP as a main ingredient, and
the absorption layer is formed using InGaAs or InGaAsP as a main ingredient.

8. An optical receiver comprising:
the light-receiving element according to claim 1, which condenses and transmits incident signal light; and
a control unit that performs predetermined control, based on intensity of light detected by the light-receiving element.

9. An optical module comprising:
a signal light emission unit that emits signal light;
the light-receiving element according to claim 1, which condenses and transmits the emitted signal light;
a local oscillation light emission unit that emits local oscillation light;
a lens unit that condenses the emitted local oscillation light;
a multiplexing unit that multiplexes signal light that passes through the light-receiving element and the condensed local oscillation light to emit a multiplexed light signal; and
a conversion unit that converts a multiplexed light signal emitted from the multiplexing unit, into an electric signal, wherein
the local oscillation light emission unit adjusts intensity of local oscillation light to be emitted, based on intensity of light detected by the light-receiving element.
